(19) United States
(12) Patent Application Publication
(10) Pub. No.: US 2009/0212405 A1
(43) Pub. Date: Aug. 27, 2009

(54) STACKED DIE MOLDED LEADLESS PACKAGE

(76) Inventors: Yong Liu, Scarborough, ME (US); Zhongfa Yuan, Suzhou (CN); Erwin lan Almagro, Dumaguete City (PH)

Correspondence Address: HISCOCK & BARCLAY, LLP, 2000 HSBC PLAZA, 100 Chestnut Street, ROCHESTER, NY, 14604-2404, US

(21) Appl. No.: 12/037,471

(22) Filed: Feb. 26, 2008

(51) Int. Cl. H01L 23/495; H01L 21/60

(52) U.S. Cl. 257/670; 438/109; 257/E23.04; 257/E23.034; 257/E21.51; 257/E21.514

(57) ABSTRACT

A stacked die molded leadless package (MLP) stacks two dice and uses leads formed integrally with top and central clips and a leadframe to avoid wire bonding. The central clip leads are source and gate leads leading to source and gate portions of the central clip common to source and gate regions of both dice. The top clip and leadframe are thus connected to the drain regions of the upper and lower dice, the leads of the top clip being drain leads connected to the leadframe leads. The central clip and leadframe leads provide source, gate, and drain terminals in the finished MLP. A method of making the MLP includes flip-chip assembly of the clips, dice, and leadframes in pairs or greater simultaneous quantities. Spacers can be employed between connected components to ensure proper alignment and distribution of bonding material.

### BACKGROUND AND SUMMARY

1. Field of the Invention

The present invention relates to a multi-chip packaged semiconductor module, and more particularly, to a multi-chip packaged semiconductor module with enhanced heat dissipation.

2. Description of the Related Art

Generally, semiconductor devices such as diodes, thyristors, or MOS gate devices, for example, metal-oxide-semiconductor field effect transistors (MOSFET) and insulated gate bipolar transistors (IGBT), are formed in a silicon semiconductor die. In a vertical MOSFET the die includes a metal drain electrode at its lower surface, and a metal source electrode and a gate electrode on its upper surface. The die is attached to a surface of a leadframe pad, and electrodes are electrically connected to the leadframe by a wire bonding. For vertical MOSFETs, the die pad may also be a lead. The MOSFET die or is attached to a surface of a leadframe pad, and electrodes on the die are electrically connected to leads of the leadframe by a wire bonding. The leadframe temporarily holds the leads in place. A typical leadframe has two parallel rails with a number of cross rails. A die pad in the center is supported by tie bars that extend from the rails toward the center of the frame. Other leads extend from The leads extend from the rails toward the center of the frame but do not support the die. Consequently, the electrodes on the die are electrically connected to proximate ends of leads of the leadframe. The distal ends of the leads protrude out of a molded housing. The MOSFET die and the wires are completely molded in the housing.

A conflict arises since there is a demand for smaller and smaller semiconductor devices, while speed, power, and capacity are expected to increase. Various solutions have arisen to provide compromise solutions. For example, die stacking has been used to conserve space by using a single leadframe to which two dies are attached, typically one on the top of the leadframe and one on the bottom of the leadframe. However, prior art arrangements typically include capacity limiting drain arrangements, such as having a single set of drain leads for the drain regions. Other arrangements provide for higher drain capacity by leaving the drain regions of the dies exposed on the top and bottom of the package, but this can create a problem when it comes time to place the package in a device being manufactured. There is thus a need for more compact, higher capacity semiconductor packages with more convenient attachment arrangements.

An additional problem that can arise is heat dissipation. Since electronic components, such as diodes and ICs, produce heat, it is important to have a way to remove heat from the components to prevent overheating, which can adversely affect performance of the components or even cause them to fail. Prior art arrangements offer heat dissipation arrangements, but it is always desirable to have more efficient heat dissipation allowing electronic components to operate at lower temperatures when feasible and not overly expensive.

An example of such a multiple die package is shown in FIG. 1. In FIG. 1, a semiconductor device 5 includes two stacked dies 30, 32 attached to a leadframe 11. The leadframe 11 includes a plurality of leads 12 and top and bottom source attach areas 20, 22, on the top and bottom surfaces 21, 23 of the leadframe 11. One die 30 is attached to the top source attach area 20 and another die 32 is attached to the bottom source attach area 22 with solder bumps 31. A drain clip assembly 50 attached to the top of the upper die 30, the drain clip assembly 50 coupling drain leads 12 of the leadframe and drain regions of the upper die 30. The resulting package has stacked dies with one drain clip assembly that relies on contact between the upper die drain clip 52 and the drain leads 56 of a side rail 53. In addition, the package includes two gate leads. While the package yields a dual-channel device and provides enhanced thermal dissipation, there is room for improvement in heat dissipation and the package disadvantageously leaves silicon of at least one of the dies partly exposed.

Another prior art semiconductor package is shown in FIG. 2. Here also dies 12, 13 are attached to the top and bottom of a lead frame 11, but there is no drain clip assembly. Rather, the drain regions 21, 22 of the top and lower dies 12, 13 remain exposed for connection as appropriate. This results in a more compact assembly, but leaves room for improvement in heat dissipation. In addition, as with the package shown in FIG. 1, a surface of each die is left exposed, the silicon of which is then susceptible to damage.

Embodiments provide a dual channel stacked die molded leadless package (MLP) product with industry standard size and pin out that allows drop-in replacement for industry accepted packages. Embodiments further provide high electrical and thermal performance as a result of exposed top and bottom pads, which also serve as drain connections. The pads are formed as parts of respective clips that are larger than the dies mounted thereon so as to provide larger thermal capacity than prior art arrangements. Spacers can be included in embodiments to ensure uniform thicknesses of multiple layer of bonding material, and V-shape grooves on one or both die attach pads (DAPs) can help to prevent failures, such as delamination and moisture. Embodiments can also provide a universal land pattern of the exposed DAP dimensions. Employing two 90 degree clips (top and central) according to embodiments with the die attach pads between the clips and ensures that the die spacing is uniform even without spacers. Further, the MLP of embodiments has no exposed silicon.

These results are achieved in embodiments by using a central clip that includes the source and gate leads of the MLP and that provides conduits for heat dissipation. The sources and gate terminals of both dies are attached to the central clip, while the drain of the lower die is connected to a DAP on a leadframe and the drain of the upper die is attached to a DAP on the top clip. Preferably, all connections use conductive materials, such as conductive epoxy or solder, and can include spacers to better ensure proper alignment of the surfaces being connected. A flip and attach process is preferable used to connect the upper die to the top clip and to connect the lower die to the central clip. To facilitate this arrangement, embodiments employ a leadframe that features a DAP to which the lower die drain terminal and top clip drain leads are attached, the bottom portion of the leadframe DAP being left exposed after molding to provide a drain connection and improve the electrical and thermal performance. The resulting dual channel stacked die MLP has high capacity, more efficient heat dissipation, and avoids the use of bonding wires and associated wire bonding of the prior art.

### BRIEF DESCRIPTION OF THE DRAWINGS

FIG. 1 schematically illustrates the components of a prior art flipped leaded molded package (FLMP).

FIG. 2 schematically illustrates another prior art FLMP with stacked dice.

FIG. 3 is a schematic perspective top view of a completed MLP according to embodiments disclosed herein.

FIG. 4 is a schematic perspective view of the bottom of a completed MLP according to embodiments disclosed herein and as seen in FIG. 3.

FIG. 5 is a schematic perspective view of a completed MLP according to embodiments disclosed herein and showing the internal structure of the MLP.

FIG. 6 is a schematic exploded view of a MLP according to embodiments disclosed herein.

FIG. 7 is a schematic perspective view of a top clip of a MLP according to embodiments disclosed herein.

FIG. 8 is a schematic perspective view of a central clip of a MLP according to embodiments disclosed herein.

FIG. 9 is a schematic perspective view of a leadframe of a MLP according to embodiments disclosed herein.

FIG. 10 is a schematic perspective view of an assembly arrangement according to embodiments disclosed herein and bearing two top clips.

FIG. 11 is a schematic perspective view of an assembly arrangement according to embodiments disclosed herein and bearing two central clips.

FIG. 12 is a schematic perspective view of an assembly arrangement according to embodiments disclosed herein and bearing two leadframes.

FIG. 13 is a schematic illustration of a method of assembly of a top portion of a MLP according to embodiments.

FIG. 14 is a schematic illustration of a method of assembly of a central portion of a MLP according to embodiments.

FIG. 15 is a schematic illustration of a method of assembly of a bottom portion of a MLP according to embodiments, as well as joining of the completed dual top portion assembly arrangement and the completed dual central portion assembly arrangement are joined with the completed bottom portion.

FIG. 16 is a schematic illustration of the completed assembly of the dual top, central, and bottom portions of the MLP according to embodiments disclosed herein.

FIG. 17 is a schematic illustration of the completed dual MLP assembly after molding according to embodiments disclosed herein.

FIG. 18 is a schematic illustration of two completed MLPs as seen in FIG. 17 after the completed dual MLP assembly has been singulated, such as by sawing, according to embodiments disclosed herein.

FIG. 19 is a schematic ghost view illustration of the MLP of embodiments including spacers.

FIG. 20 is a schematic exploded view of a MLP according to embodiments employing an alternate orientation of the source, gate, and drain leads.

FIG. 21 is a schematic ghost perspective view of embodiments showing the internal structure of a completed MLP employing the alternate arrangement of FIG. 20.

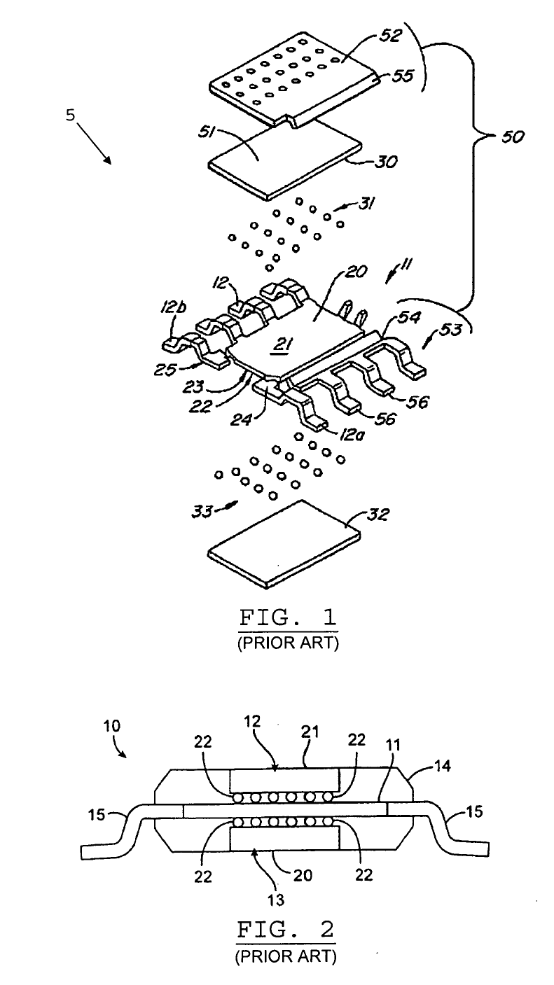

### DESCRIPTION

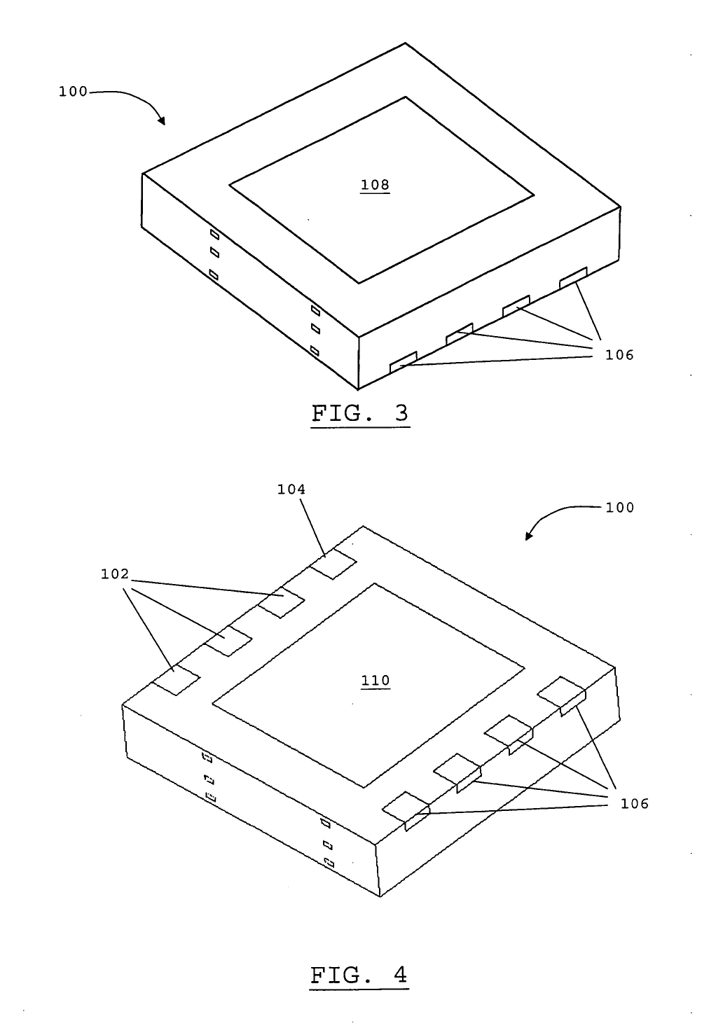

With reference to the accompanying FIGS., a molded leadless package (MLP) 100 according to embodiments is shown in FIG. 3-4 and includes source terminals 102, a gate terminal 104, drain terminals 106, and exposed drain pads 108, 110 of or connected to the top and lower dies 112, 114. While a single gate terminal 104 is shown in the FIGS., it should be understood that more such gate terminals can be included as befits the requirements of a given application. Preferably, to protect the silicon of the dies 112, 114, the drain pads 108, 110 are surfaces of structure to which the dies 112, 114 are bonded, as will be described below.

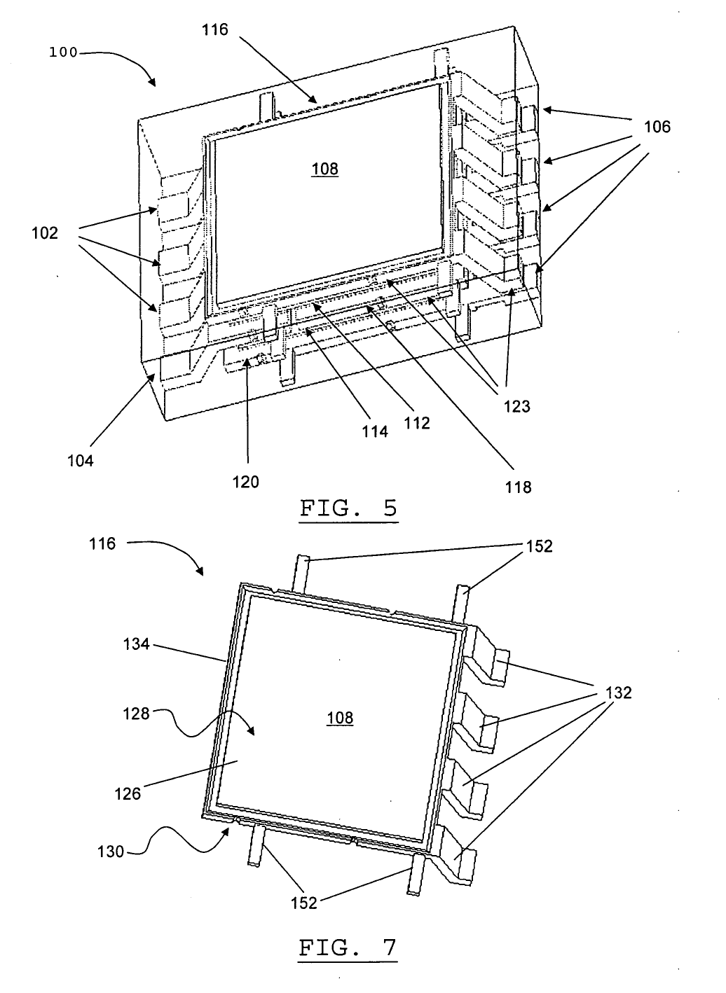

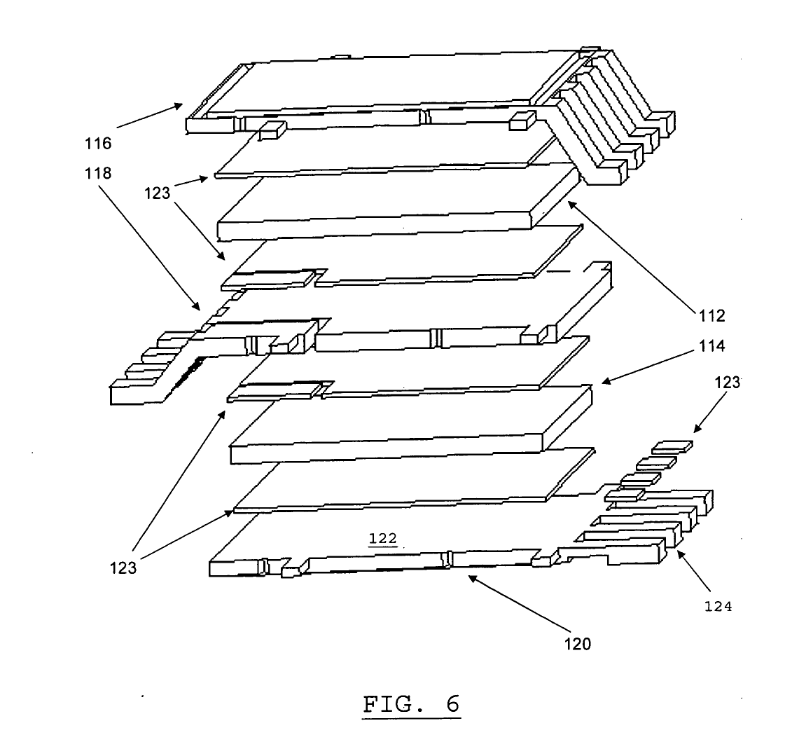

As seen in FIGS. 5-7, the MLP includes a top clip 116 to which an upper die 112 is bonded, a central clip 118 to which the top and lower dies 112, 114 are bonded, and a leadframe 120 with a die attach pad (DAP) 122, to which the lower die 114 is attached and that includes at least one leadframe drain lead 124 extending from the DAP 122. The top clip 116, as seen particularly in FIG. 7, includes an upper die attach pad 126 with a top surface 128 on drain 108, a bottom surface 130, and at least one top clip lead 132 projecting from an edge of the top clip 116. The top clip lead(s) 132 have a generally Z-shaped profile and are sized to reach from the top clip 116 to the tops of the drain leads 124 of the leadframe 120 shown in FIG. 6. Preferably, the top clip 116 includes a groove 134, such as a V-shaped groove, around its perimeter to reduce the likelihood of delamination, damage from moisture, and other types of failure of the MLP 100.

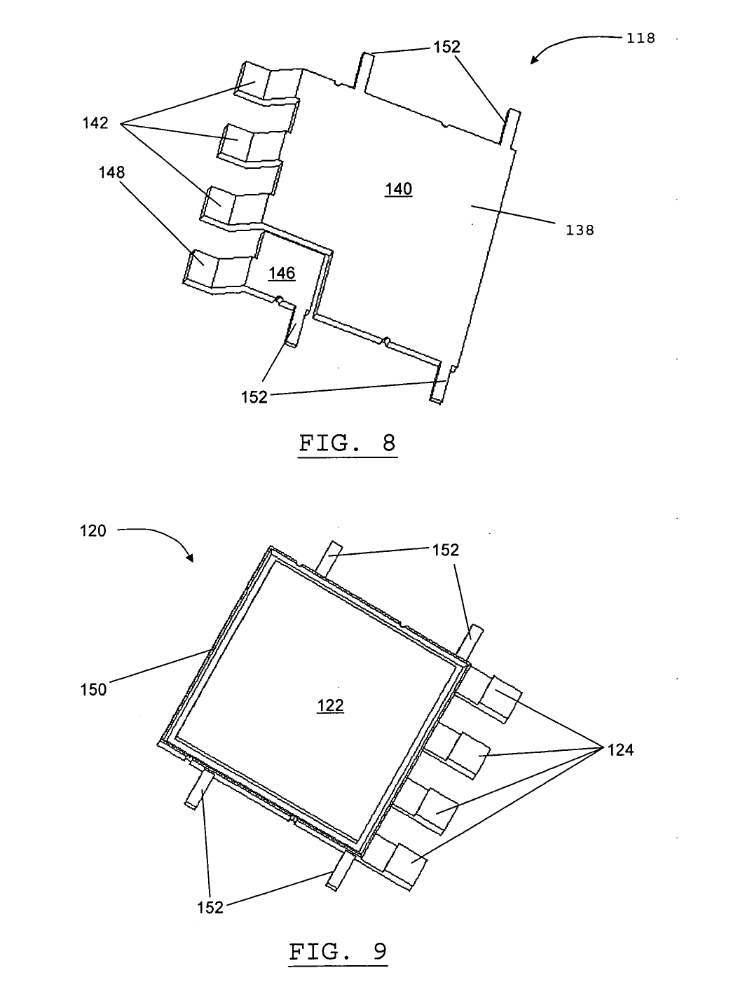

As seen particularly in FIG. 8, the central clip 118 includes a central DAP 138 with a source portion 140 having at least one source lead 142 projecting from an edge of the source portion 140. The central clip pad 138 also includes a gate portion 146 adjacent to the source portion 140, outer edges thereof preferably being aligned with outer edges of the source portion 140 to form a substantially rectangular perimeter of substantially identical dimension to that of the top clip DAP 126. The gate portion 140 includes at least one gate lead 148 projecting from an edge thereof, preferably in substantially identical form and parallel to the at least one source lead 142 projecting from the edge of the source portion 140 of the central clip pad 138. It should be understood that more than one gate portion, each with at least one gate lead, can be formed on the central clip 118, depending on the requirements of the particular dies and application. The source and gate leads 142, 148 can be generally Z-shaped and are sized so that their bottom surfaces are aligned with the bottom surface of the leadframe 120. Preferably, the source and gate leads 142, 148 are also sized to provide source and gate terminals 102, 104 in the outer surface of the completed MLP 100.

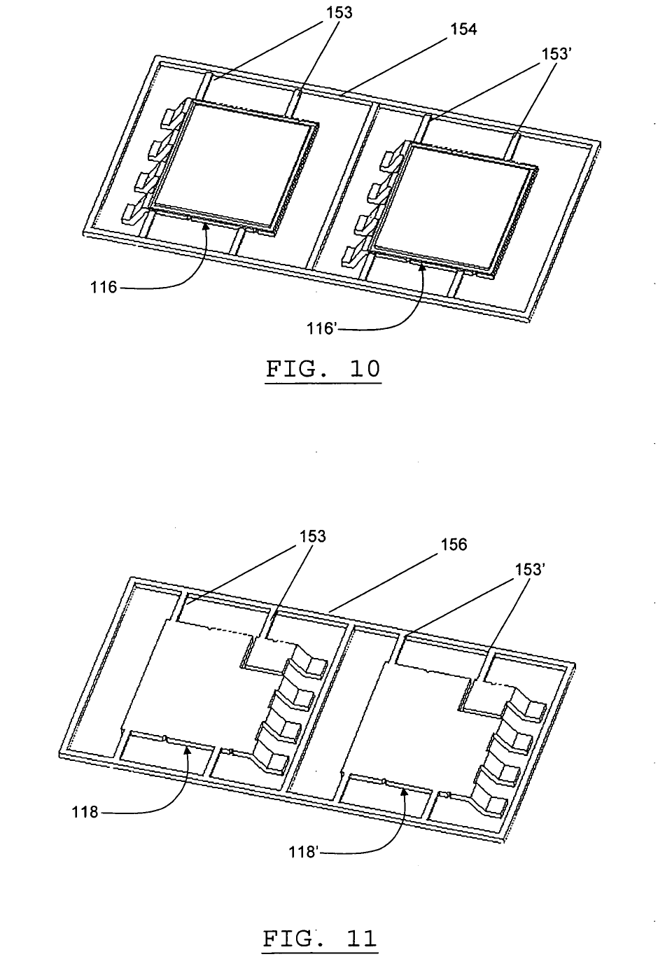

As seen in FIG. 9, the leadframe 120 of embodiments preferably includes a bottom DAP 122 having a substantially rectangular perimeter of substantially identical dimension to the central clip pad 138 and the top clip pad 126. Preferably, the leadframe 120 has a groove 150, such as a V-shaped groove, formed between the bottom DAP 122 and the edges of the leadframe 120, the groove 150 reducing the likelihood of failure, such as delamination and failure due to the presence of moisture. The leadframe 120 advantageously includes at least one drain lead 124 projecting from at least one edge thereof. The leadframe drain leads 124 are preferably formed integrally with the leadframe 120 and sized to engage the drain leads 132 of the top clip pad 126 when the MLP 100 is assembled and to provide drain terminals 106 in the external surface of the completed MLP 100 as seen, for example, in FIG. 4.

The arrangement of the leads of the top clip, the central clip, and the leadframe allow proper connections to be made between the source, gate, and drain regions of the dies and the terminals of the completed MLP with only the various leads and the DAPs. Thus, embodiments advantageously eliminate the need for the use of wires between the dies and the terminals, which eliminates the need for wire bonding while providing high capacity and heat dissipation.

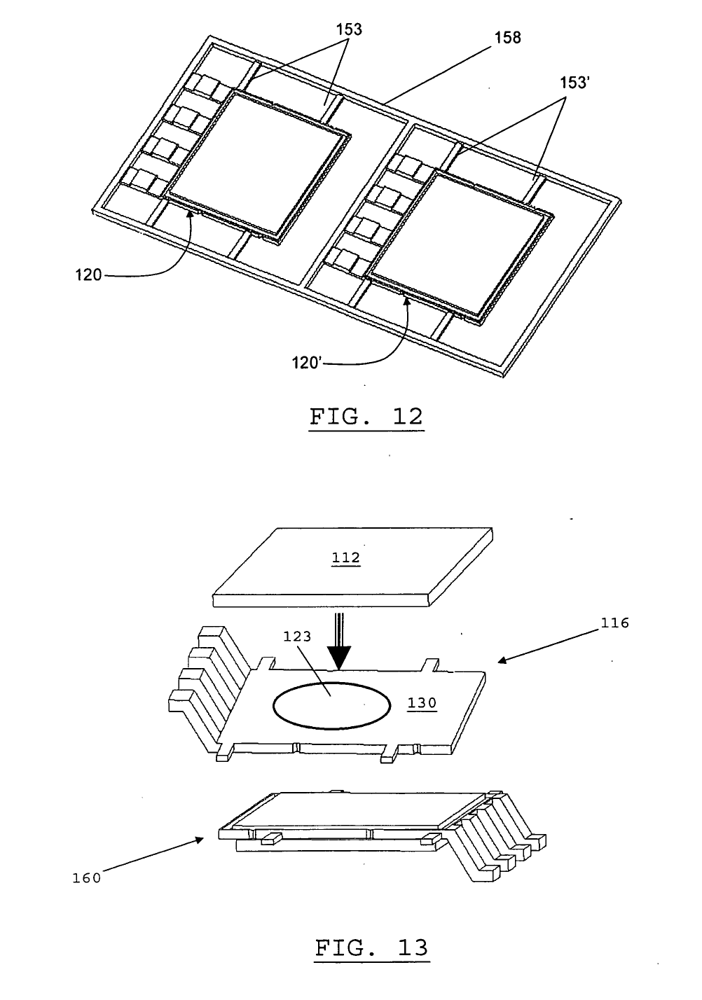

As seen particularly in FIGS. 7-9, the top clip 116, central clip 118, and leadframe 120 include projections 152 on opposed edges thereof adjacent to the lead edges thereof. The projections 152 are the remains of tie bars that attach the clips 116, 118 and leadframe 120 to frames 154, 156, 158, seen in FIGS. 10-12 and 15-16, that allow easier manipulation of the clips and assembly of two or more MLPs at a time. For example, with particular reference to FIGS. 10-12, a top frame 154 can include two top clips 116, 116′, while a central frame 156 can include two central clips 118, 118′, and a bottom frame 158 can include two bottom leadframes 120, 120′. In each of the frames 154, 156, 158, projections tie bars 153, 153′ hold the clips and leadframes in place, resulting in projections 152 after singulation. While two of each clip and the leadframe are shown in the FIGS., it should be understood that more or fewer can be included on each frame depending on the particular needs of the user.

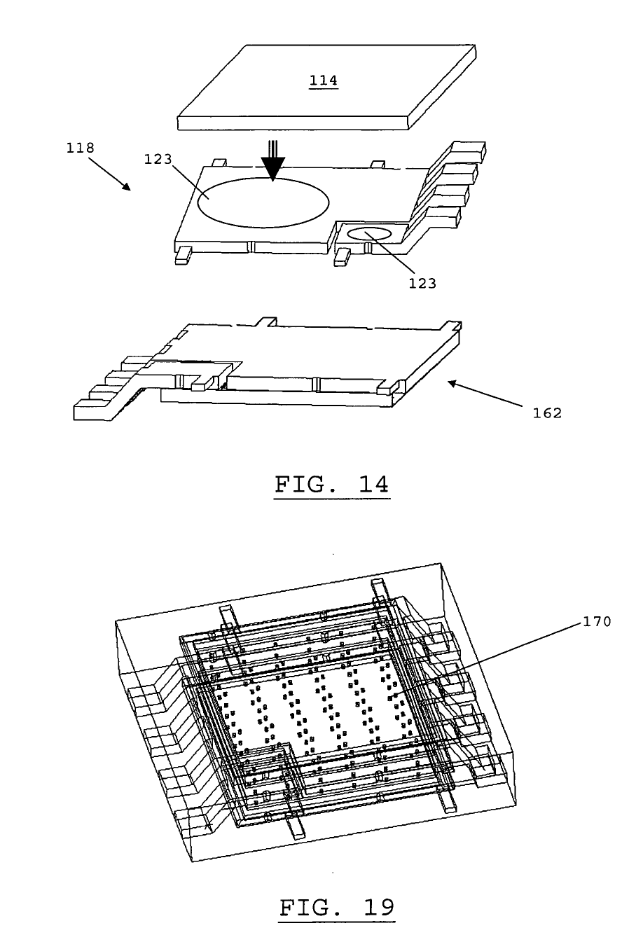

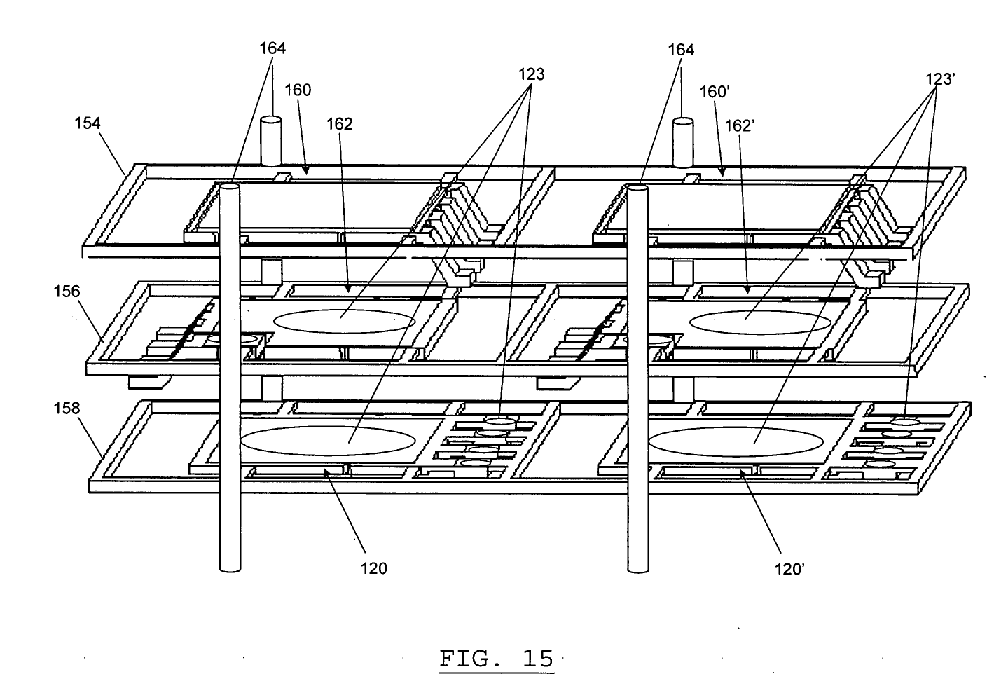

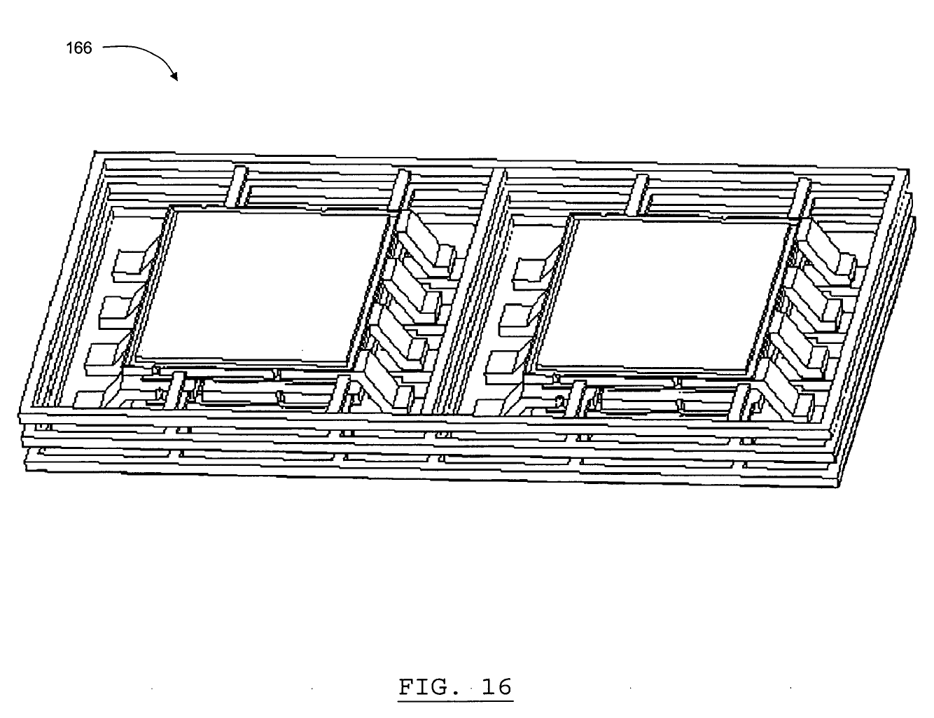

To assemble the inventive MLP 100, it is advantageous that each die 112, 114 first be attached to a respective DAP. For relative ease of explanation of the method of assembly, components and assembly of portions only one MLP are shown in FIGS. 7-9, 13, and 14. Thus, as seen, for example, in FIG. 13, a top clip 116 is preferably prepared by turning it upside down and placing conductive bonding material 123, such as conductive epoxy, solder, or another suitable bonding material, on a bottom surface of the top DAP 126. Once the bonding material 123 is applied, the upper die 112 is attached to the bottom surface 130 by pressing it onto the bonding material 123. Once the bonding is complete, the top clip assembly 160 is flipped over so that it is once again right side up with the upper die 112 underneath. Preferably, this is done with a pair of top clips 116, 116′ in a frame 154 so that a pair of top clip assemblies 160, 160′ are ready for the next phase of MLP assembly, such as can be seen in FIGS. 15 and 16.

Similarly, as seen, for example, in FIG. 14, a central clip 118 is preferably flipped upside down and conductive bonding material is preferably applied to the exposed bottom surfaces of the source and gate portions 140, 146 of the central clip DAP 138. The lower die 114 is then attached to the bottom of the DAP 138 by placing the lower die 114 on the bonding material 123. Once bonding is complete, the central clip assembly 162 is righted in preparation for its next phase in the MLP 100 assembly. Preferably, this is done with a pair of central clips 118, 118′ in a frame 156 so that a pair of central clip assemblies 162, 162′ are ready for the next phase of MLP assembly, such as can be seen in FIGS. 15 and 16.

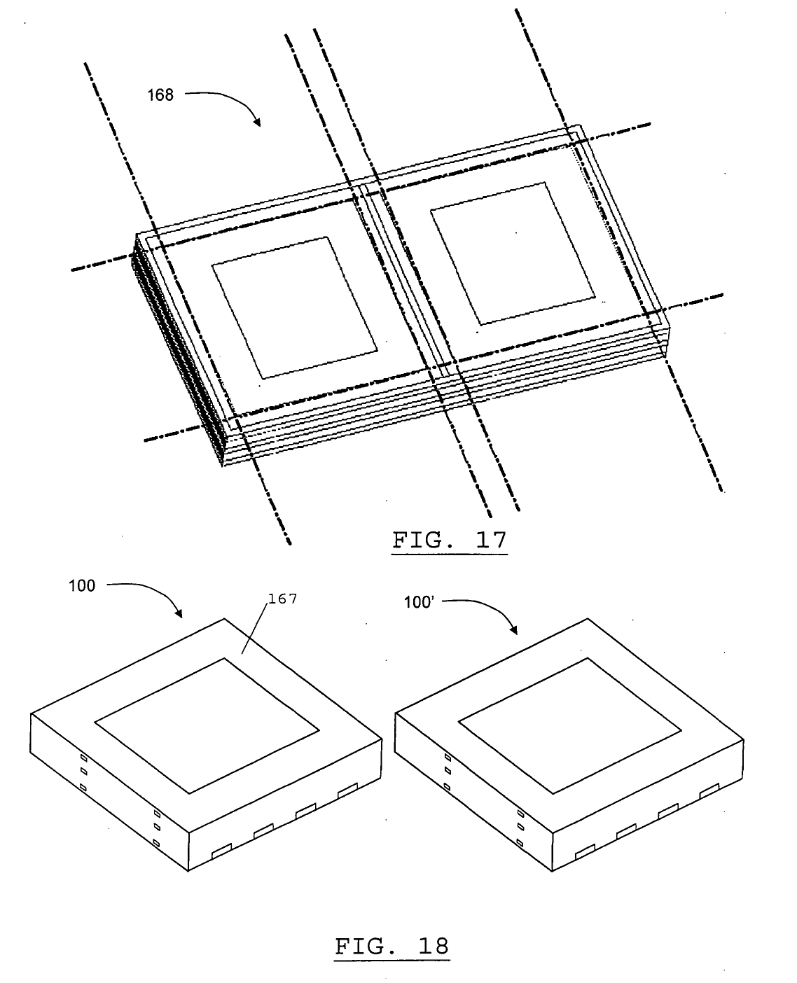

With reference to FIGS. 15 and 16, when the top and central clip assemblies 160, 160′, 162, 162′ are ready, conductive bonding material 123 is applied to the top surfaces of the central and bottom DAPs 138, 122, as well as to the top surfaces of the leadframe drain leads 124. The frames 154, 156, 158 are then aligned, preferably with the aid of guides 164, and pressed together to bond them into an MLP assembly 166. The MLP assembly 166 is then molded with a molding material 167, such as a resin, a thermally setting epoxy, or the like, and the molded MLP assembly 168 is singulated, such as by sawing or other ways of cutting, to form two MLPs 100, 100′ and to expose the terminals 102, 104, 106 of the MLPs 100, 100′ as shown in FIGS. 17 and 18. The molding material 167 serves to maintaining the structural relationship between the clips, leadframe, and leads, and also assists with dissipation of heat generated by the dies during operation of the MLP. Thus, it is advantageous to use a thermally conductive molding material.

Alternatively, the upper die 112 can be flip-attached onto the DAP 126 of the top clip 116 with pre-dispensed bonding material, such as pre-dispensed flux, which can facilitate a first pass reflow process. Solder bumps, if included, are then reflowed to couple the upper die 112 to the top clip DAP 126. Similarly, assembly of the central potion includes flipping the lower die 114 onto the source and gate attach areas 140, 146 of the central clip 118 with pre-dispensed bonding material 123, such as pre-dispensed flux, which can facilitate the first pass reflow process. Solder bumps, if included on the central clip 118 or the lower die 114, are then reflowed to couple the lower die 114 to the central clip 118. The top and central clips 116, 118 then undergo an additional chip attach process in which the upper die is attached to the top of the source and gate portions 140, 146 of the central clip 118 and the lower die 114 and top clip leads 132 are connected to the leadframe 120, preferably with pre-dispensed bonding material 123, such as pre-dispensed flux. A second pass reflow process is then performed, preferably done at a lower temperature compared to the first pass so that the solder of the top and central initial flipchip attach processes does not reflow. A body is then placed around the assembly and the two are preferably coupled to one another through a transfer molding process. As is known in the industry, the semiconductor device is then completed by degating, debarring and dejuncting the semi-completed semiconductor device. The semiconductor device is deflashed, the body is marked, if desired, and the leads are plated, trimmed, and formed.

As illustrated in FIG. 19, spacers 170 can be employed between bonded components to ensure proper alignment and uniform thickness of layers of bonding material 123 between the dies 112, 114 and respective DAPs, as described below. Ensuring uniform thickness of bonding material layers can advantageously avoid die tilt that could result in a corner of one or more of the dies contacting the DAP, which can induce cracking of the die.

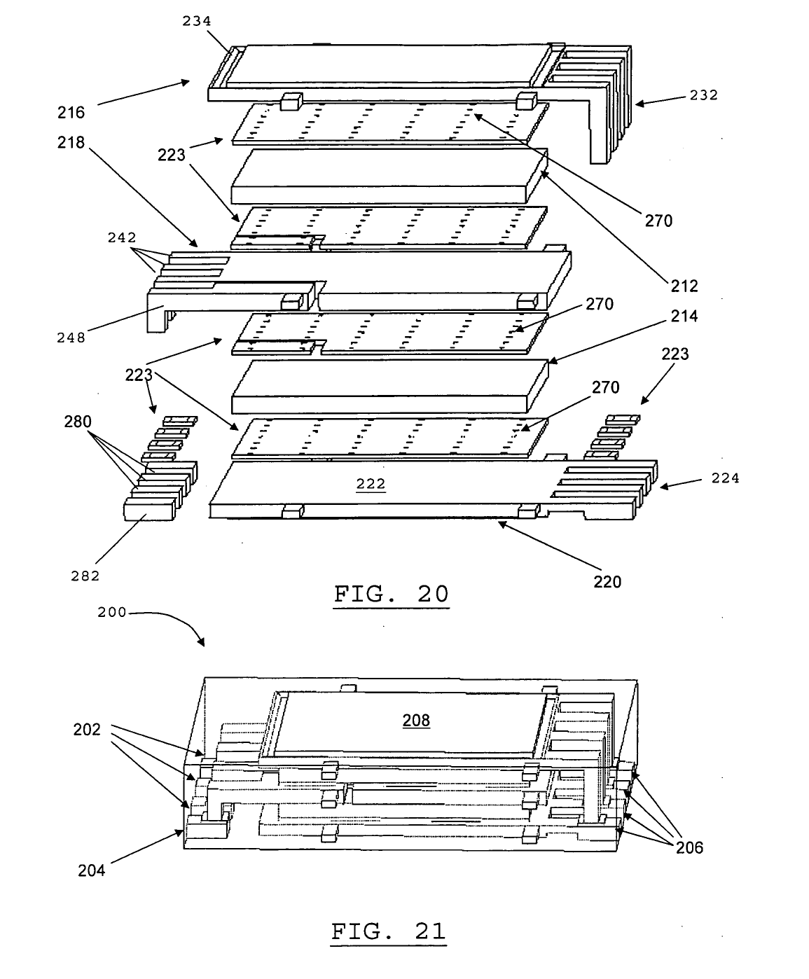

Embodiments can employ a variation of the leads for the top and central clips, as seen in FIGS. 20 and 21 for a slightly more compact MLP 200. The configuration of the top clip 216 is substantially unchanged apart from changing the leads 232 from Z-shaped to right angle profiles. As with the earlier described exemplary embodiment, the top clip 216 preferably includes a groove 234, such as a V-shaped groove, to reduce likelihood of failure, such as by delamination. The central clip 218 also is largely unchanged but for the alteration of the source and gate leads 242, 248 to right angle profiles. Employing right angle profiles in the top clip 216 and/or the central clip 218 can help to generate uniform thickness of layers of bonding material 223, which can avoid die tilt and thus help to prevent die cracking. The bottom leadframe 220 adds at least one source terminal lead 280 and at least one gate terminal lead 282 that are separate from the DAP 222. Thus, the MLP 200 includes a upper die 212 bonded to the underside of the top clip 216 with bonding material 223, such as by flip attaching, and the lower die 214 is bonded to the underside of the central clip 218 in similar fashion. The top and central clip assemblies are then joined to each other and the lower die is attached to the bottom DAP 222 with additional bonding material 223. The top clip leads 232 and central clip leads 242, 248 are attached to leadframe drain leads 224 and source and gate terminal leads 280, 282 with bonding material 223, as well. Preferably, the process is performed with pairs of clips and leadframes as in the previously described exemplary embodiment. The bonded top, central, and bottom parts are then molded and cut as in the previously described exemplary embodiment to form a MLP 200 that is slightly more compact than the MLP 100 and has source and gate terminals 242, 248 isolated from the bottom DAP 222. As shown in FIGS. 20 and 21, spacers 270 can be employed to ensure proper alignment of and distance between the various components, as well as to ensure that the layers of bonding material 223 have substantially uniform thickness. While the spacers 270 are shown in FIG. 20 as being placed in the bonding material 223, the spacers 270 can be placed on the bonding surfaces of the DAPs, or can be placed on the bonding surfaces of the dies, depending on the particular requirements of the user.

In all embodiments disclosed herein, such as seen in FIGS. 19-21, spacers 170, 270 can be employed to uniform thickness of the bonding material 123 and/or to minimize die tilt. As suggested above, the spacers 170, 270 can placed in the bonding material 123, can be placed on the bonding surfaces of the DAPs, and/or can be placed on the bonding surfaces of the dies. The spacers 170, 270 can be formed from any suitable material, such as solder, copper, gold, or intermetallic compounds. For example, if the spacers are to be placed in the bonding material, intermetallic compound grains of known and controlled size can be introduced into solder. Thus, during assembly, when bonding material 123 is introduced and liquefied, the spacers 170, 270 are introduced into the liquefied bonding material 123. The spacers 170, 270 could instead be included in the bonding material 123 prior to placement on the components to be joined.

As another example, if the spacers are to be placed on the bonding surfaces of the DAPs, then the spacers can be bumps of high melting point solder/gold mixture or other appropriate material(s). Soft material can be printed on or otherwise attached to the same bonding surfaces with bumped spacers or opposite surfaces of the DAPs. Similarly, as a further example, additional spacers formed on the bonding surfaces of the dies can be bumps of high melting point solder/gold mixture or other appropriate material. When bumps are employed, they can be formed as part of the assembly process or can be preformed on the components before assembly is begun. Preferably, the central clip 118, 218 features an array of unitary spacers 170 on its bottom and top surfaces, the top clip 116, 216 features an array of unitary spacers 170, 270 on its bottom surface, and the leadframe 120, 220 includes an array of spacers 170, 270 on its top surface to ensure uniform thickness of conductive bonding materials 123 and to reduce or eliminate die tilt.

Thus, the present invention provides a semiconductor device that includes two dice stacked with the central clip therebetween providing a common source region and a common gate region, the leadframe being connected to the lower die and to drain leads of the top clip to serve as a common drain clip. Such parallel connection of the first and second chips greatly increases the silicon performance of the high power chips that generally may be accommodated in typical semiconductor packages while maintaining generally existing package layouts and eliminating the need for wire bonding. Such dual channel parallel connection structure may also increase the reliability of the system. For example, if one channel chip fails, another channel chip may still work. Further, embodiments provide greater thermal dissipation and better protection of the silicon of the dies by providing drain pads in the clips, preferably larger than the dies themselves.

It will be appreciated that various of the above-disclosed and other features and functions, or alternatives thereof, may be desirably combined into many other different systems or applications. It will also be understood that various presently unforeseen or unanticipated alternatives, modifications, variations or improvements therein may be subsequently made by those skilled in the art which are also intended to be encompassed by the following claims. While the embodiments described above include vertical MOSFETS with a drain contact on the lower surface and source and gate contacts on the upper surface, those skilled in the art understand that other devices including and not limited to diodes, LDMOS, IGBTs, thyristors, bipolar transistors, and integrated circuits may be substituted to produce stacked dies with three or more clips that remove heat from the packaged multi-chip module.

What is claimed is:

1. A method of making a multi-chip packaged semiconductor module, the method comprising:
providing a top clip with a plurality of top clip leads;
providing a central clip with a plurality of central clip leads;
providing a leadframe with plurality of leadframe leads;
placing an upper die on a bottom surface of the top clip with bonding material therebetween;
placing a lower die on a bottom surface of the central clip with bonding material therebetween;
placing a bottom surface of the upper die on a top surface of the central clip with bonding material therebetween;
placing a bottom surface of the lower die on a top surface of the leadframe with bonding material therebetween; and
placing bottoms of the top clip leads on the leadframe leads with bonding material therebetween.

2. The method of claim 1 wherein placing an upper die on a bottom surface of the top clip comprises:
orienting the top clip with the bottom surface up;
placing bonding material on the bottom surface;
placing the upper die on the bonding material;
bonding the upper die to the bottom surface to form a top clip assembly; and
flipping the top clip assembly so that the top surface of the top clip is upward.

3. The method of claim 1 wherein placing a lower die on a bottom surface of the central clip comprises:
orienting the central clip with the bottom surface up;
placing bonding material on the bottom surface;
placing the lower die on the bonding material;
bonding the lower die to the bottom surface to form a central clip assembly; and
flipping the central clip assembly so that the top surface of the central clip is upward.

4. The method of claim 1 wherein placing a bottom surface of the upper die on a top surface of the central clip comprises:
orienting the top clip with its bottom surface down;
orienting the central clip with its bottom surface down;
placing bonding material on the top surface of the central clip;
placing the upper die on the bonding material; and
bonding the upper die to the top surface of the central clip.

5. The method of claim 1 wherein placing a bottom surface of the lower die on a top surface of the leadframe comprises:
orienting the central clip with its bottom surface down;
orienting the leadframe clip with its bottom surface down;
placing bonding material on the top surface of the leadframe;
placing the lower die on the bonding material; and
bonding the lower die to the top surface of the leadframe.

6. The method of claim 1 wherein placing bottom surfaces of the top clip leads on top surfaces of the leadframe leads comprises:
orienting the top clip with its bottom surface down;
orienting the leadframe clip with its bottom surface down;
placing bonding material on the top surfaces of the leadframe leads;
placing the bottom surfaces of the top clip leads on the bonding material; and
bonding the bottom surfaces of the top clip leads to the top surfaces of the leadframe leads.

7. The method of claim 1 wherein:
placing an upper die on a bottom surface of the top clip comprises:
orienting the top clip with the bottom surface up;
placing bonding material on the bottom surface;
placing the upper die on the bonding material;
bonding the upper die to the bottom surface to form a top clip assembly; and
flipping the top clip assembly so that the top surface of the top clip is upward;
placing a lower die on a bottom surface of the central clip comprises:
orienting the central clip with the bottom surface up;
placing bonding material on the bottom surface;
placing the lower die on the bonding material;
bonding the lower die to the bottom surface to form a central clip assembly; and
flipping the central clip assembly so that the top surface of the central clip is upward;
placing a bottom surface of the upper die on a top surface of the central clip, placing a bottom surface of the lower die on a top surface of the leadframe, and placing bottom surfaces of the top clip leads on top surfaces of the leadframe leads are performed at the same time and comprise:
orienting the top clip assembly with the bottom surface of the upper die down;
orienting the central clip assembly with the bottom surface of the lower die down;
orienting the leadframe with its bottom surface down;
placing bonding material on the top surface of the central clip;
placing bonding material on the top surface of the leadframe;
placing bonding material on the top surfaces of the leadframe leads;
placing the bottom surfaces of the top clip leads on the bonding material; and
placing the upper die on the bonding material on the top surface of the of the central clip assembly, the lower die on the bonding material on the top surface of the leadframe, and the bottom surfaces of the top clip leads on the bonding material on the top surfaces of the leadframe leads; and
bonding the upper die, lower die, and top clip leads to the top surface of the central clip, the top surface of the leadframe, and the top surfaces of the leadframe leads, respectively.

8. The method of claim 1 wherein placing bonding material comprises placing heat activated bonding material and bonding comprises heating the material.

9. The method of claim 8 wherein placing heat activated bonding material comprises placing solder.

10. The method of claim 8 wherein placing heat activated bonding material comprises placing heat activated conductive adhesive.

11. A multi-chip packaged semiconductor module comprising:
a top clip with at least one lead projecting from an edge thereof;
a central clip with at least two leads projecting from an edge thereof;
a leadframe with at least one lead projecting from an edge thereof, the top clip and central clip being stacked on the leadframe;
an upper die attached to a bottom surface of the top clip and to a top surface of the central clip; and
a lower die attached to a bottom surface of the central clip and a top surface of the leadframe.

12. The multi-chip packaged semiconductor module of claim 11 wherein the top clip lead are arranged over and attached to the leadframe leads.

13. The multi-chip packaged semiconductor module of claim 11 wherein the central clip includes a first portion and a second portion, at least one of the at least two central clip leads is at least one first central clip lead projecting from the first portion, and at least one of the at least two central clip leads is at least one second central clip lead projecting from the second portion.

14. The multi-chip packaged semiconductor module of claim 13 wherein the first portion is a source portion, the at least one first central clip lead is a source lead, the second portion is a gate portion, and the at least one second central clip lead is a gate lead.

15. The multi-chip packaged semiconductor module of claim 13 wherein the upper and lower dies each include first and second regions attached to the first and second portions of the central clip.

16. The multi-chip packaged semiconductor module of claim 15 wherein the first portion is a source portion, the first regions are source connect regions, the second portion is a gate region, and the second regions are gate connect regions.

17. The multi-chip packaged semiconductor module of claim 11 wherein the drain region of the upper die is connected to the top clip and the at least one top clip lead is a drain lead.

18. The multi-chip packaged semiconductor module of claim 11 wherein the drain region of the lower die is connected to the leadframe and the at least one leadframe lead is a drain lead.

19. The multi-chip packaged semiconductor module of claim 11 wherein each at least one top clip lead has a generally Z-shaped profile sized and arranged so that a bottom surface of an end portion of each top clip lead reaches a top surface of at least one at least one leadframe lead.

20. The multi-chip packaged semiconductor module of claim 11 wherein each at least one central clip lead has a generally Z-shaped profile sized and arranged so that a bottom surface of an end portion of each central clip lead is substantially coplanar with a bottom surface of the leadframe.

21. The multi-chip packaged semiconductor module of claim 11 wherein each at least one top clip lead has a generally inverted L-shaped profile sized and arranged so that a bottom surface of an end portion of each top clip lead reaches a top surface of at least one at least one leadframe lead.

22. The multi-chip packaged semiconductor module of claim 11 further comprising at least one bottom terminal lead substantially coplanar to the leadframe and wherein each central clip lead has a generally inverted L-shaped profile sized and is arranged so that a bottom surface of an end portion of each central clip lead substantially reaches a top surface of corresponding bottom terminal lead.

23. The multi-chip packaged semiconductor module of claim 11 wherein spacers are interposed between surfaces of attached components to ensure proper alignment of the surfaces and substantially uniform thickness of bonding material interposed between attached components.

24. The multi-chip packaged semiconductor module of claim 23 wherein the spacers are grains placed in the bonding material used between attached components.

25. The multi-chip packaged semiconductor module of claim 23 wherein the spacers are bumps formed on a surface of at least one of the top clip, the upper die, the central clip, the lower die, and the leadframe.

26. A method of making a multi-chip packaged semiconductor module comprising:
a top clip with at least one lead projecting from an edge thereof;
a central clip with at least two leads projecting from an edge thereof;
a leadframe with at least one lead projecting from an edge thereof, the top clip and central clip being stacked on the leadframe;
an upper die attached to a bottom surface of the top clip and to a top surface of the central clip; and
a lower die attached to a bottom surface of the central clip and a top surface of the leadframe; and
the method making the chip device comprising:
attaching the upper die to the bottom surface of the top clip by:
orienting the top clip with the bottom surface up;
placing bonding material on the bottom surface;
placing the upper die on the bonding material;
bonding the upper die to the bottom surface to form a top clip assembly; and
flipping the top clip assembly so that the top surface of the top clip is upward;
attaching the lower die to the bottom surface of the central clip by:
orienting the central clip with the bottom surface up;
placing bonding material on the bottom surface;
placing the lower die on the bonding material;
bonding the lower die to the bottom surface to form a central clip assembly; and
flipping the central clip assembly so that the top surface of the central clip is upward;
attaching the bottom surface of the upper die to the top surface of the central clip, attaching the bottom surface of the lower die to the top surface of the leadframe, and attaching the bottom surfaces of the top clip leads to the top surfaces of the leadframe leads are performed at the same time by:
orienting the top clip assembly with the bottom surface of the upper die down;
orienting the central clip assembly with the bottom surface of the lower die down;
orienting the leadframe with its bottom surface down;
placing bonding material on the top surface of the central clip;
placing bonding material on the top surface of the leadframe;
placing bonding material on the top surfaces of the leadframe leads;
placing the bottom surfaces of the top clip leads on the bonding material; and
placing the upper die on the bonding material on the top surface of the of the central clip assembly, the lower die on the bonding material on the top surface of the leadframe, and the bottom surfaces of the top clip leads on the bonding material on the top surfaces of the leadframe leads; and
bonding the upper die, lower die, and top clip leads to the top surface of the central clip, the top surface of the leadframe, and the top surfaces of the leadframe leads, respectively.
